(19) United States
(12) Patent Application Publication
(10) Pub. No.: US 2026/0347695 A1
(43) Pub. Date: Nov. 5, 2026

(54) METHOD OF SYNTHESIS OF COLLOIDAL InSb QUANTUM DOTS

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE GRENOBLE ALPES, SAINT-MARTIN-D'HÈRES (FR)

(72) Inventors: Peter REISS, Grenoble (FR); Yongju KWON, Grenoble (FR)

(73) Assignees: COMMISSARIAT À L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE GRENOBLE ALPES, SAINT-MARTIN-D'HÈRES (FR)

(21) Appl. No.: 19/488,940

(22) PCT Filed: Jun. 2, 2023
(86) PCT No.: PCT/IB2023/000480

§ 371 Date: Dec. 1, 2025

(51) Int. Cl. C09K 11/75; B82Y 20/00; B82Y 40/00; C09K 11/02; C22C 1/00; C22C 30/00; H10D 62/81; H10D 62/85

(52) U.S. Cl. CPC C09K 11/75; C09K 11/025; C22C 1/007; C22C 30/00; H10D 62/812; H10D 62/85; B82Y 20/00; B82Y 40/00

(57) ABSTRACT

The present invention relates to a method of synthesis of colloidal InSb quantum dots (InSb QDs) comprising a premixing step of In and Sb precursors at a temperature of less than 100 °C, under stirring.

### FIELD OF THE INVENTION

The present invention relates to the field of quantum dots (QDs)—also called semiconductor nanocrystals, in particular to InSb quantum dots (InSb QDs)—also called InSb nanocrystals.

### BACKGROUND

Narrow band gap colloidal quantum dots (QDs) offer exceptional promises for low-cost infrared active applications combining many advantages such as tunable absorption and fluorescence emission spectra, high molar extinction coefficients, high photoluminescence quantum yield, high stability, cost-efficient and scalable synthesis and solution processability. One of the advantages of using Infrared (IR) radiation stems from reduced Rayleigh scattering of light in the air at longer wavelengths, induced for example by dust or fog. By consequence, short wavelength infrared (SWIR) cameras can “see” through haze better than visible cameras. Also, the use of near infrared (NIR) light enables much larger penetration depths in biological tissues to perform deep-tissue imaging. In the NIR-I (650-900 nm) and NIR-II (1000-1200 nm) regions, tissues have low scattering, absorption, and autofluorescence backgrounds. Other useful applications of colloidal IR QDs have been explored in photovoltaics, infrared light-emitting diodes (LEDs), telecommunications, luminescent solar concentrators, and optical sensing. Most of the reported NIR and/or SWIR active QDs are based on materials containing toxic heavy metals, such as PbS and HgTe QDs. A(III)-B(V) semiconductors containing one group-13 and one group-15 element of the periodic table are highly promising Pb- and Hg-free alternative materials.

Colloidal indium antimonide quantum dots (InSb QDs) have been considered as a low-toxic alternative to Pb and Hg chalcogenide IR QDs. Bulk InSb possesses a narrow direct band gap (0.17eV at 300K), high static dielectric constant (ε=17.88) and the highest room temperature electron mobility (7.7×104 cm²/V·s), the lowest thermal conductivity (0.18 W/cm·K), and the smallest exciton binding energy (0.5 meV) of all common semiconductors. Also, due to the large exciton Bohr radius of InSb (~60 nm), the bandgap energy of InSb QDs can be tuned in a large range in the NIR and SWIR spectrum through size control, benefiting from the well-known quantum confinement effect. Given the inherent advantages of colloidal synthesis methods (which are generally economic and scalable), this would allow the use of colloidal InSb QDs as building blocks in low-cost, solution-processed optoelectronic devices, such as ultrafast field-effect transistors, photodetectors, thermoelectric devices, LEDs, and solar cells, to name a few.

Concerning the chemical synthesis of colloidal QDs, which are in most cases in a size range of around 1-10 nm, it is of crucial importance to precisely control the size and to achieve a narrow size distribution as the optical and electronic properties are governed by the size due to the aforementioned quantum confinement effect. In the present specification, the term “size” means the diameter of the QDs if they are spherical and the thickness of the QD arms if they are in the form of rods or branched. The most common way to determine experimentally the size and size distribution of QDs is by using transmission electron microscopy (TEM). In addition, an indication of the size dispersion can also be obtained by analyzing the optical absorption and photoluminescence (PL) spectra: a well-defined excitonic peak in the absorption spectrum and a narrow PL emission are indicative of a narrow size distribution. US 20210214611 and M. Ginterseder et al. (J. Am. Chem. Soc. 2020, 142, 4088-4092) report the synthesis of InAs QDs using In(I)Cl and As(NMe₂)₃ as precursors, in particular indium monohalide is introduced for the first time to synthesize InAs QDs. The baseline of this approach is to apply InCl as both the In precursor and mild reducing agent for the As³, precursor which is in the +3 oxidation state. As each In⁺ ion can transfer two electrons to As³⁺, a stoichiometry of 3:1 is required according to the following equation:

3 In⁺+As³⁺→3 In³⁺+As³⁻

Only a few chemical synthesis methods for colloidal InSb QDs have been reported, due to the limited choice of suitable pnictogen precursors. In 2008, the formation of colloidal InSb QDs was reported using indium stearate and tris(trimethylsilyl) antimonide ((TMS)₃Sb) as precursors (C.M. Evans et al., Chem. Mater. 2008, 20, 5727-5730). However, tris(trimethylsilyl) antimonide, (TMS)₃Sb, is not commercially available, highly pyrophoric, air- and moisture-sensitive. Also, the high reactivity of (TMS)₃Sb precursors makes it hard to control the nucleation and growth process of InSb QDs and leads to a broad size distribution. Therefore, the obtained absorption spectrum is featureless, i.e., no excitonic peak is visible, and the photoluminescence or PL spectrum is broad. In situ formed, toxic SbH₃ has been tried as an alternative precursor for the synthesis of InSb QDs (A. Maurice et al., Part. Part. Syst. Charact. 2013, 30, 828-831). However, the synthesized InSb QDs showed once again a featureless absorption spectrum and a broad size distribution. In the quest for safer and easier use of group V precursors giving access to higher quality InSb QDs, tris(di(trimethylsilyl))amide stibine (Sb[N(SiMe₃)₂]₃) or tris(dimethylamido)antimony (Sb(NMe₂)₃) have been explored more recently (W. Liu et al., J. Am. Chem. Soc. 2012, 134, 20258-20261; M. Yarema et al., Chem. Mater. 2013, 25, 1788-1792; S. Tamang et al., Dalt. Trans. 2015, 44, 16923-16928; R.W. Crisp et al., Nanoscale 2018, 10, 11110-11116; S. Bussatto et al., ACS Nano 2020, 14, 13146-13160). Unlike the (TMS)₃Sb or SbH₃ precursors which exhibit the −3 of oxidation state for Sb, in Sb[N(SiMe₃)₂]3 and Sb(NMe₂)₃ antimony is in its +3 oxidation state, which makes the precursors more stable. On the other hand, additional reducing agents are required in these reactions to reduce Sb(III) to Sb(−III) such as
lithium triethylborohydride (LiEt₃BH) (W. Liu et al., J. Am. Chem. Soc. 2012, 134, 20258-20261; S. Tamang et al., Dalt. Trans. 2015, 44, 16923-16928; S. Bussatto et al., ACS Nano 2020, 14, 13146-13160),
lithium di(trimethylsilyl)amide (Li[N(SiMe₃)₂]) (S. Tamang et al., Dalt. Trans. 2015, 44, 16923-16928), or
n-butylithium (nBuLi) (S. Tamang et al., Dalt. Trans. 2015, 44, 16923-16928; R.W. Crisp et al., Nanoscale 2018, 10, 11110-11116),
   and then either Sb(0) reacts with In(0) or the reduced Sb(−III) can react with In(III) precursors resulting in the formation of InSb QDs.

In these reactions, the use of highly reactive reducing agents negatively impacts the reproducibility and makes it challenging to control the nucleation and growth processes of the InSb QDs. As a result, the InSb QDs formed using these reduction pathways show weak excitonic absorption features, which are still very broad indicative of a broad size distribution. To get it narrower, post-synthetic size fractionation methods, such as size-selective precipitation, can be applied, albeit these steps are time-consuming and the amount of QDs in each fraction is much lower than in the initial reaction solution.

In particular, S. Bussatto et al. (ACS Nano 2020, 14, 13146-13160) reports the synthesis of InSb QDs using In(III)Cl and Sb(NMe₂)₃ as precursors and LiEt₃BH as the reducing agent for Sb(NMe₂)₃. One key element of this work is the mixing of the In and Sb precursors at room temperature, prior to the injection of this mixture into the hot solvent (oleylamine at 240 °C). The authors claim that the preformed In-Sb bonds prevent from the formation of metallic Sb(0) nanoparticles, which is otherwise observed. The resulting InSb QDs show an excitonic absorption peak tunable from 970 to 1570 nm. However, the excitonic absorption feature is only weakly pronounced indicating a broad size distribution, and size-selective precipitation had to be used to separate smaller from larger particles in an initial bimodal size distribution. Several previous works have been reported using strong reducing agents for aminopnictogen precursors to synthesize III-V QDs. Common problems of the use of strong, highly reactive reducing agents, such as LiEt₃BH, are the formation of In(0) and Sb(0) metallic particles as side-products and the low reproducibility of the syntheses. Also, as already stated, LiEt₃BH is very sensitive to air and moisture.

W. Liu et al. (J. Am. Chem. Soc. 2012, 134, 20258-20261) reports the synthesis of InSb QDs using In(III)Cl and Sb[N(SiMe₃)₂]₃ as precursors and LiEt₃BH as the reducing agent for Sb[N(SiMe₃)₂]3. The method results in InSb QDs with a size range of 3.3-6.5 nm showing an excitonic absorption peak in the range of 1200 to 1750 nm. As mentioned before, the strong reducing agent LiEt₃BH is difficult to handle and leads to low reproducibility. Also, the antimony source Sb[N(SiMe₃)₂]₃ is not commercial and must be synthesized prior to the QD preparation. The initial size distributions of the as-synthesized InSb QDs are broad and hence size-selective precipitation had to be applied after synthesis to afford well-defined absorption peaks. Therefore, it is highly desirable to develop a novel method of synthesis of InSb QDs also called InSb nanocrystals, enabling the tuning of the nanocrystal size in a wide range and giving directly access to a narrow size distribution without additional fractionation steps.

### SUMMARY OF THE INVENTION

The present invention addresses this need and others by providing a method of synthesis of colloidal InSb quantum dots (InSb QDs) comprising the following steps:
(1) premixing In and Sb precursors wherein
   a) a solution containing of Sb(NR₁R₂)₃ with R₁ and R₂, independently, being a C₁-C₈ alkyl and/or C₆-C₁₀ aryl, in a saturated fatty amine having 4 to 20carbon atoms or an unsaturated fatty amine having 12 to 20 carbon atoms and 1 to 3 unsaturated double bonds,
      is added to
   b) a solution containing In(I)X with X being Cl, Br or I, in a saturated fatty amine having 12 to 20 carbon atoms or an unsaturated fatty amine having 12 to 20 carbon atoms and 1 to 3 unsaturated double bonds, or a saturated fatty alkane having 12 to 30 carbon atoms, or in an unsaturated fatty alkene having 12 to 30 carbon atoms and 1 to 6 unsaturated double bonds, or in a mixture of several of these compounds,
      the resulting mixture is heated to a temperature of less than 100 °C, under stirring;
(2) synthesizing InSb quantum dots (InSb QDs) wherein
   a) a solvent or a solvent mixture selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds,
      is heated to a temperature of 150 to 400 °C,
   b) the solution obtained in (1) and a coordinating agent selected in a group consisting of C₄-C₂₅ alkyl phosphines, C₄-C₂₅ alkyl phosphine oxides, C₄-C₂₅alkyl phosphonic acids, C₄-C₂₅ alkyl phosphinic acids,
      are introduced in the solvent or solvent mixture
      i) at a temperature of 150 to 400 °C, and the resulting mixture is maintained at a temperature of 150 to 400 °C, for 1 minute to 5 hours, under stirring (hot-injection method); or
      ii) at a temperature of 20 to 30 °C, and the resulting mixture is heated with a temperature rise to 150 to 400 °C, and the resulting mixture is maintained at a temperature of 150 to 400 °C, for 1 minute to 5 hours, under stirring (heat-up method). In the present specification, the terms “InSb quantum dots (QDs)” and “InSb nanocrystals” will be used interchangeably.

The InSb QDs obtained by the method of the invention, give access to a broader wavelength range than the InAs QDs of the state of the art. The latter is of high importance for numerous applications, such as for example in SWIR photodetectors. More specifically, the InAs QDs prepared according to US 20210214611 and M. Ginterseder et al., J. Am. Chem. Soc. 2020, 142, 4088-4092, exhibit a 1^{st} excitonic absorption peak wavelength tunable from 704 to 1363 nm, while the excitonic peaks of the InSb QDs synthesized with the method of the invention can be controlled from 750 nm to 1900 nm. Moreover, the prepared InSb QDs exhibit spherical morphology, whereas the InAs QDs of US 20210214611 and M. Ginterseder et al. (J. Am. Chem. Soc. 2020, 142, 4088-4092), have tetrapod geometry, in particular when they are produced at lower temperatures (<250 °C) or at shorter reaction times. This is less favorable than spherical geometry for further application of the QDs because it is more difficult to i) grow a homogeneous shell on the surface of tetrapods, to improve the photoluminescence or PL emission efficiency, and ii) assemble the QDs in thin dense films as required, for example, in photodetectors. Finally, when simply transposing the procedure reported for InAs QDs in US 20210214611 and M. Ginterseder et al., J. Am. Chem. Soc. 2020, 142, 4088-4092, InSb QDs having distinct excitonic features cannot be obtained.

When compared to the method in S. Busatto et al. (ACS Nano 2020, 14, 13146-13160), unlike LiEt₃BH used by the authors as the reducing agent, the method of synthesis of the invention uses In(I)X with X as defined above, as a mild reducing agent for Sb(NR₁R₂)₃. In(I)X with X as defined above, is safer to use, easier to handle and results in InSb QDs with clearly defined excitonic peaks in a large size range, without applying post-synthetic size fractionation steps. The present synthesis method resulted in InSb QDs having a broader wavelength region for a 1^{st} excitonic absorption peak wavelength from 750 to 1900 nm.

Compared to W. Liu et al. (J. Am. Chem. Soc. 2012, 134, 20258-20261), the method of the invention does not need additional size fractionation steps to achieve high-quality InSb QDs with a clear absorption peak tunable in a broader range. Moreover, unlike Liu et al. where the antimony source Sb[N(SiMe₃)₂]₃ is not commercial, the method of the invention fully relies on commercially available precursors.

Another object of the present invention is the use of a method according to the invention for manufacturing infrared biological imaging devices, NIR/SWIR photodetectors, telecommunications (1.4 μm) detectors/detectors compatible with the wavelengths used in fiber optics (1.3 and 1.55 μm), solar cells, infrared light-emitting diodes (LEDs), ultrafast field-effect transistors, or thermoelectric devices.

A further object of the invention is a method for manufacturing infrared biological imaging devices, NIR photodetectors, telecommunications (1.4 μm) detectors, solar cells, infrared light-emitting diodes (LEDs), ultrafast field-effect transistors, or thermoelectric devices comprising the steps of

a) synthesizing colloidal InSb quantum dots (InSb QDs) according to the method of the invention;
b) surface engineering of InSb QDs;
c) fabrication of InSb QD thin films; and
d) integration of the QD thin film in the (opto-)electronic device.

The order of steps b), c) and d) will depend on the application.

### BRIEF DESCRIPTION OF THE DRAWINGS

The invention is further described by the following drawings and examples which illustrate embodiments thereof. These examples and drawings should not in any way be interpreted as limiting the scope of the present invention.

FIG. 1 represents VIS-NIR absorption spectra of InSb QDs synthesized according to the invention using different experimental parameters (FIG. 1a). The synthesized InSb QDs have zinc blende structure and the XRD pattern performed using a Bruker D8 powder diffractometer equipped with a copper anode (λKα1=1.5406 Å, (λKα2=1.5444 Å) and an X'celerator 1D detector, shows that they are phase-pure (FIG. 1b). The stoichiometry between In and Sb in InSb core QDs which have a 1^{st} excitonic absorption peak at 1314 nm is analyzed as 1:0.87 (atomic ratio) and EDX data suggests that Br is bound to the surface (FIG. 1c). The obtained InSb QDs have roughly spherical shape with an average diameter of 3.9 nm (FIG. 1d).

FIG. 2 represents the dependence of the VIS-NIR absorption data of InSb QDs obtained using different In(I) halides for reactions performed at 230 °C: In(I)Cl (FIG. 2a), In(I)Br (FIG. 2b), In(I)I (FIG. 2c). (d) is a graph showing the evolution of the 1^{st} excitonic absorption peak position (full symbols) and of its line width (FWHM, hollow symbols) as a function of the reaction time and indium precursor.

FIG. 3 represents the TEM analysis using a TECNAI F20 microscope operated at 200 kV, which shows that the size of the InSb QDs synthesized with In(I)Br or In(I)I according to the presented procedure can be tuned at least in a range from around 2 to 7 nm (FIGS. 3a, 3b, 3c, 3d).

FIG. 4 represents the comparison of syntheses products synthesized with premixing of In(I) and Sb(III) or without premixing. (a) Vis-NIR absorption spectra of the synthesis products from In(I)Br and Sb(NMe₂)₃ with premixing the precursors before heating to 230 °C (solid line) and without the premixing and injection of the Sb precursor into the hot solution of the In precursor (dotted line). XRD patterns of the syntheses products obtained (b) with premixing, (c) without premixing using a Bruker D8 powder diffractometer equipped with a copper anode (λKα1=1.5406 Å, (λKα2=1.5444 Å) and an X'celerator 1D detector. The reference diffraction patterns of bulk InSb, In₂O₃ and In(0) are also given for comparison. TEM images of the synthesis products obtained (d) with premixing, (e) without premixing.

FIG. 5 represents the solvent dependence of the absorption spectra of the InSb QDs. Vis-NIR absorption spectra of aliquots taken over time during syntheses of InSb QDs from (a) In(I)Cl and Sb(NMe₂)₃ in ODE, (b) In(I)Cl and Sb(NMe₂)₃ in OAm, (c) In(I)Br and Sb(NMe2)3 in ODE, (d) In(I)Br and Sb(NMe2)3 in OAm, (e) In(I)I and Sb(NMe₂)₃ in ODE, (f) In(I)I and Sb(NMe₂)₃ in OAm at 230 °C. (g) is a graph showing the evolution of the 1st excitonic absorption peak position (full symbols) and of its line width (FWHM, hollow symbols) as a function of the reaction time for the different reaction conditions.

FIG. 6 represents the temperature dependence of the optical properties of the InSb QDs in ODE.

Vis-NIR absorption spectra of aliquots taken over time during syntheses of InSb QDs from In(I)Br and Sb(NMe₂)₃ at (a) 230 °C, (b) 260 °C, and (c) 280 °C in ODE. (d) is a graph showing the 1^{st} excitonic absorption peak position (full symbols) and its line width (FWHM, hollow symbols).

Vis-NIR absorption spectra of aliquots taken over time during syntheses of InSb QDs from In(I)I and Sb(NMe₂)₃ at (e) 230 °C, (f) 260 °C, and (g) 280 °C in ODE. (h) is a graph showing the 1^{st} excitonic absorption peak position (full symbols) and its line width (FWHM, hollow symbols).

FIG. 7 represents the temperature dependence of the optical and morphological properties of InSb QDs synthesized in OAm. Vis-NIR absorption spectra of aliquots taken over time during the synthesis of InSb QDs from In(I)I and Sb(NMe₂)₃ at (a) 210 °C, (b) 230 °C, (c) 250 °C, (d) 280 °C, and (e) 320 °C in OAm. (f) Graph showing the 1^{st} excitonic absorption peak position (full symbols) and its line width (FWHM, hollow symbols). TEM images of the InSb QDs obtained at (g) 230 °C after 60 min and (h) at 280 °C after 30 min.

FIG. 8 represents the effect of the precursor molar ratio on the optical properties of the InSb QDs. Vis-NIR absorption spectra of aliquots taken over time during syntheses of InSb QDs from In(I)Cl: Sb(NMe₂)₃ molar ratio of (a) 3:1 and (b) 6:1 in OAm at 230 °C. (c) is a graph showing the 1^{st} excitonic absorption peak position (full symbols) and its line width (FWHM, hollow symbols) for the 6:1 ratio.

Vis-NIR absorption spectra of aliquots taken over time during syntheses of InSb QDs from In(I)Br: Sb(NMe₂)₃ molar ratio of (d) 3:1 and (e) 6:1 in OAm at 230 °C. (f) is a graph showing the 1^{st} excitonic absorption peak position (full symbols) and its line width (FWHM, hollow symbols) for the different conditions.

FIG. 9 represents the effect of the ligands on the optical properties of the InSb QDs. Vis-NIR absorption spectra of aliquots taken over time during syntheses of InSb QDs from In(I)I and Sb(NMe₂)₃ with TOP ligands using an In: Sb: TOP molar ratio of (a) 3:1:4, (b) 3:1:8, and (c) 3:1:0 at 230 °C in OAm.

(d) Vis-NIR absorption spectra of aliquots taken over time during syntheses of InSb QDs from In(I)I and Sb(NMe₂)₃ with TBP ligands using an In: Sb: TBP molar ratio of 3:1:4 at 230 °C in OAm.
(e) Vis-NIR absorption spectra of aliquots taken over time during syntheses of InSb QDs from In(I)I and Sb(NMe₂)₃ with additional DDPA ligands using an In: Sb: TOP :DDPA molar ratio of 3:1:4:1 at 230 °C in OAm. (f) is a graph showing the 1^{st}excitonic absorption peak position (full symbols) and its line width (FWHM, hollow symbols) for the different conditions.

FIG. 10 represents the precursor concentration dependence of the optical properties of the InSb QDs. Vis-NIR absorption spectra of aliquots taken over time during syntheses of InSb QDs with (a) 80 mM of In(I)I and 26 mM of Sb(NMe₂)₃ and (b) 40 mM of In(I)I and 13 mM of Sb(NMe₂)₃ at 230 °C in OAm. (f) is a graph showing the 1^{st} excitonic absorption peak position (full symbols) and its line width (FWHM, hollow symbols) for the different conditions.

FIG. 11 represents the absorption and PL spectra of InSb QDs obtained by reacting In(I)Br and Sb(NMe₂)₃ after premixing in oleylamine in 230 °C for 60 min. The PL peak is fitted by a Gaussian function.

FIG. 12 represents ¹H-NMR analyses of the premixed InSb precursor solution containing In(I)I, Sb(NMe₂)₃, and dodecylamine (DDA). ¹H-NMR spectra of (a) Sb(NMe₂)₃, (b) DDA, (c) Sb(NMe₂)₃ with 3 equiv. of DDA, (d) In(I)I with 3 equiv. of DDA, and (e) a mixture of 3 equiv. of In(I)I, 1 equiv. of Sb(NMe₂)₃ and 3 equiv. of DDA in toluene-d8, preheated to 50 °C for 1 hr.

FIG. 13 represents the synthesis of InSb QDs using DDA instead of OAm in combination with In(I)I and Sb(NMe₂)₃ (reaction temperature: 230 °C).

FIG. 14 represents the Vis-NIR absorption spectrum (solid line) of InSb QDs (dotted line) obtained by reacting In(I)Br with Sb(NMe₂)₃ at 260 °C in ODE for 60 min, grown further by a secondary injection of precursor solution (In(I)Br with Sb(NMe₂)₃ in OAm) using a syringe pump over a period of 15 min (3 mL/h) at 260 °C.

FIG. 15 represents the Vis-NIR absorption spectra of InSb QDs from In(I)I and Sb(NMe₂)₃ at 230 °C obtained using (a) the heat-up or (b) the hot-injection method.

### DETAILED DESCRIPTION OF THE INVENTION

The present invention is a method of synthesis of colloidal InSb quantum dots (InSb QDs) comprising the following steps:
(1) premixing In and Sb precursors wherein
   a) a solution containing of Sb(NR₁R₂)₃ with R₁ and R₂, independently, being a C₁-C₈ alkyl and/or C₆-C₁₀ aryl, in a saturated fatty amine having 4 to 20 carbon atoms or an unsaturated fatty amine having 12 to 20 carbon atoms and 1 to 3 unsaturated double bonds,
      is added to
   b) solution containing In(I)X with X being Cl, Br or I, in a saturated fatty amine having 12 to 20 carbon atoms or an unsaturated fatty amine having 12 to 20 carbon atoms and 1 to 3 unsaturated double bonds, or a saturated fatty alkane having 12 to 30 carbon atoms, or in an unsaturated fatty alkene having 12 to 30 carbon atoms and 1 to 6 unsaturated double bonds, or in a mixture of several of these compounds,
      the resulting mixture is heated to a temperature of less than 100 °C, under stirring;
(2) synthesizing InSb quantum dots (InSb QDs) wherein
   a) a solvent or a solvent mixture selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds,
      is heated to a temperature of 150 to 400 °C,
   b) the solution obtained in (1) and a coordinating agent selected in a group consisting of C₄-C₂₅ alkyl phosphines, C₄-C₂₅ alkyl phosphine oxides, C₄-C₂₅ alkyl phosphonic acids, C₄-C₂₅ alkyl phosphinic acids,
      are introduced in the solvent or solvent mixture
      i) at a temperature of 150 to 400 °C, and the resulting mixture is maintained at a temperature of 150 to 400 °C, for 1 minute to 5 hours, under stirring; or
      ii) at a temperature of 20 to 30 °C, and the resulting mixture is heated with a temperature rise to 150 to 400 °C, and the resulting mixture is maintained at a temperature of 150 to 400 °C, for 1 minute to 5 hours, under stirring.

According to an embodiment of the invention, in step (2),
a) a solvent or a solvent mixture selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds, is heated to a temperature of 150 to 400 °C,
b) the solution obtained in (1) and a coordinating agent selected in a group consisting of C₄-C₂₅ alkyl phosphines, C₄-C₂₅ alkyl phosphine oxides, C₄-C₂₅ alkyl phosphonic acids, C₄-C₂₅ alkyl phosphinic acids,
   are introduced in the solvent or solvent mixture at a temperature of 150 to 400 °C, and the resulting mixture is maintained at a temperature of 150 to 400 °C, for 1 minute to hours, under stirring.

According to another embodiment of the invention, in step (2),
a) a solvent or a solvent mixture selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds,
   is heated to a temperature of 150 to 400 °C,
b) the solution obtained in (1) and a coordinating agent selected in a group consisting of C₄-C₂₅ alkyl phosphines, C₄-C₂₅ alkyl phosphine oxides, C₄-C₂₅ alkyl phosphonic acids, C₄-C₂₅ alkyl phosphinic acids, are introduced in the solvent or solvent mixture at a temperature of 20 to 30 °C, and the resulting mixture is heated with a temperature rise to 150 to 400 °C, and the resulting mixture is maintained at a temperature of 150 to 400 °C, for 1 minute to 5 hours, under stirring.

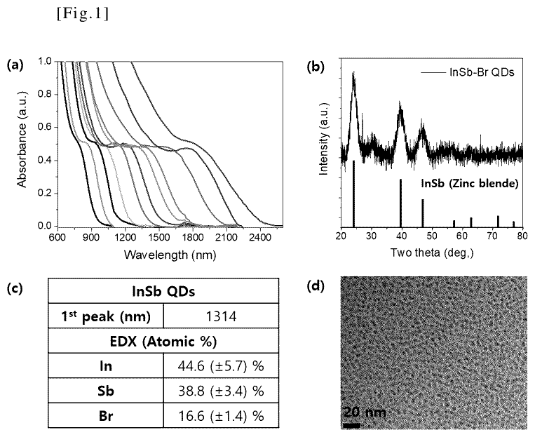

The inventors developed a novel method for synthesizing colloidal IR-active InSb QDs using In(I)Cl, In(I)Br or In(I)I in combination with Sb(NR₁R₂)₃ as the precursors and without the addition of a strong reducing agent. Especially with In(I)Br and In(I)I precursors, high-quality InSb QDs have been obtained, showing a low size distribution (around 10% of standard deviation) and a well-defined excitonic peak without the use of post-synthetic size fractionation procedures. The size of the InSb QDs (around 2-7 nm) and the position of the excitonic peak (around 750 to 1900 nm) could be varied in a broad range (FIG. 1a) by adjusting the reaction parameters (halide type: InCl, InBr or InI), reaction temperature, reaction time) as will be discussed in more details below. One key step of the present method is to obtain narrow size distributions is the premixing of the In and Sb precursors, leading presumably to the formation of intermediate complexes or clusters containing preformed In—Sb bonds. In fact, the inventors observed in an unexpected manner, that to get pure InSb QDs without any byproducts like In(0) and Sb(0) metal, premixing of In(I)X (with X=Cl, Br, or I) and Sb(NR₁R₂)₃ before heating to high temperature, is a critical step. The inventors observed that if the precursors are not premixed, they tend to be reduced to In(0) and Sb(0) metallic products.

As briefly mentioned above, the main differences between the present invention and US 20210214611 and M. Ginterseder et al. (J. Am. Chem. Soc. 2020, 142, 4088-4092), are:
the use of Sb(NR₁R₂)₃ instead of As(NMe₂)₃ giving access to InSb QDs instead of InAs QDs,
the premixing of the In and Sb precursors in the present method, prior to the reaction, while in the reported reaction the Sb precursor is injected into the hot solution of the In precursor,
the use of other indium monohalides, namely In(I)Br and In(I)I: the reported prior art reaction applies In(I)Cl, which gives, in the method of the invention, polydisperse samples with broad excitonic features,
the suppression of dodecylphosphonic acid, which is used in the standard synthesis reported in the cited art, as a strong ligand to achieve a narrow size distribution.

Furthermore, unlike S. Busatto et al. (ACS Nano 2020, 14, 13146-13160) who carried out the premixing of the In and Sb precursors so as to avoid the formation of metallic Sb(0) nanoparticles due to the faster reduction kinetics than that of the In precursor in a reaction scheme using the strong reductant LiBEt₃H, in the method of the invention, no strong reducing agents are applied. Without the premixing step a mixture of In(0), In₂O₃ and very large InSb nanoparticles are obtained.

The InSb QDs synthesized according to the method of the invention have zinc blende structure and the XRD analysis performed using a Bruker D8 powder diffractometer equipped with a copper anode (λKα1=1.5406 Å, λKα2=1.5444 Å) and an X'celerator 1D detector shows that they are phase-pure without any metallic byproducts (FIG. 1b). The stoichiometry between In and Sb in InSb core QDs which have a 1^{st} excitonic absorption peak at 1314 nm is analyzed as 1:0.87 (atomic ratio) and Energy Dispersive X-Ray Analysis (EDX) data obtained using a Zeiss Ultra 55+ scanning electron microscope equipped with a Bruker QUANTAX energy-dispersive X-ray probe suggests that Br was bound to the surface (FIG. 1c). The obtained InSb QDs have approximately spherical shape with an average diameter of 3.9 nm (FIG. 1d).

The terms “C₁₋₈ alkyl” and “C₄₋₂₅ alkyl” as used herein, refer to saturated, straight- or branched-chain radicals derived from a hydrocarbon moiety containing respectively, from 1 to 8 and 4 to 25 carbon atoms by removal of a single hydrogen atom.

Non limiting examples of C₁₋₈ alkyl radicals include methyl, ethyl, n-propyl, isopropyl, n-butyl, iso-butyl, sec-butyl, sec-pentyl, isopentyl, tert-butyl, n-pentyl, neopentyl, n-hexyl, sec-hexyl, n-heptyl, 2-methylhexane, 3-methylhexane, 2,2-dimethylpentane, 2,3-dimethylpentyl, 2,4-dimethylpentyl, 3,3-dimethylpentyl, 3-ethylpentane, 2,2,3-trimethylbutyl, n-octyl, 2-methylheptyl, 3-methylheptyl (2 enantiomers), 4-methylheptyl, 3-ethylhexyl, 2,2-dimethylhexyl, 2,3-dimethylhexyl (2 enantiomers), 2,4-dimethylhexyl (2 enantiomers), 2,5-dimethylhexyl, 3,3-dimethylhexyl, 3,4-dimethylhexyl (2 enantiomers), 3-ethyl-2-methylpentyl, 3-ethyl-3-methylpentyl, 2,2,3-trimethylpentyl (2 enantiomers), isooctyl, 2,3,3-trimethylpentyl, 2,3,4-trimethylpenty1,2,2,3,3-tetramethylbutyl.

Non limiting examples of C₄₋₂₅ alkyl radicals n-butyl, iso-butyl, sec-butyl, sec-pentyl, isopentyl, tert-butyl, n-pentyl, neopentyl, n-hexyl, sec-hexyl, n-heptyl, 2-methylhexane, 3-methylhexane, 2,2-dimethylpentane, 2,3-dimethylpentyl, 2,4-dimethylpenty1, 3,3-dimethylpentyl, 3-ethylpentane, 2,2,3-trimethylbutyl, n-octyl, 2-methylheptyl, 3-methylheptyl (2 enantiomers), 4-methylheptyl, 3-ethylhexyl, 2,2-dimethylhexyl, 2,3-dimethylhexyl (2 enantiomers), 2,4-dimethylhexyl (2enantiomers), 2,5-dimethylhexyl, 3,3-dimethylhexyl, 3,4-dimethylhexyl (2enantiomers), 3-ethyl-2-methylpentyl, 3-ethyl-3-methylpentyl , 2,2,3-trimethylpentyl (2 enantiomers), isooctyl, 2,3,3-trimethylpentyl, 2,3,4-trimethylpentyl, n-nonyl, 2,2-dimethylheptyl, 2,3-dimethylheptyl, 2,4-dimethylheptyl, 2,5-dimethylheptyl, 2,6-dimethylheptyl, 3,3-dimethylheptyl, 3,4-dimethylheptyl, 3,5-dimethylheptyl, 4,4-dimethylheptyl, 3-ethylheptyl, 4-ethylheptyl, 2,2,3-trimethylhexyl, 2,2,4-trimethylhexyl, 2,2,5-trimethylhexyl, 2,3,3-trimethylhexyl, 2,3,4-trimethylhexyl, 2,3,5-trimethylhexyl, 2,4,4-trimethylhexyl, 3,3,4-trimethylhexyl, 3-ethyl-2-methylhexyl, 4-ethyl-2-methylhexyl, 3-ethyl-3-methylhexyl, 3-ethyl-4-methylhexyl, n-decyl, 2-methylnonyl, 3-methylnonyl, 4-methylnonyl, 5-methylnonyl, 3-ethyloctyl, 4-ethyloctyl, 2,2-dimethyloctyl, 2,3-dimethyloctyl, 2,4-dimethyloctyl, 2,5-dimethyloctyl, 2,6-dimethyloctyl 2,7-dimethyloctyl, 3,3-dimethyloctyl, 3,4-dimethyloctyl, 3,5-dimethyloctyl, 3,6-dimethyloctyl, 4,4-dimethyloctyl, 4,5-dimethyloctyl, 4-propylheptyl, 4-isopropylheptyl, 3-ethyl-2-methylheptyl, 3-ethyl-3-methylheptyl, 3-ethyl-4-methylheptyl, 3-ethyl-5-methylheptyl, 4-ethyl-2-methylheptyl, 4-ethyl-3-methylheptyl, 4-ethyl-4-methylheptyl, 5-ethyl-2-methylheptyl, 2,2,3-trimethylheptyl, 2,2,4-trimethylheptyl, 2,2,5-trimethylheptyl, 2,2,6-trimethylheptyl, 2,3,3-trimethylheptyl, 2,3,4-trimethylheptyl, 2,3,5-trimethylheptyl, 2,3,6-trimethylheptyl, 2,4,4-trimethylheptyl, 2,4,5-trimethylheptyl, 2,4,6-trimethylheptyl, 2,5,5-trimethylheptyl, 3,3,4-trimethylheptyl, 3,3,5-trimethylheptyl, 3,4,4-trimethylheptyl, 3,4,5-trimethylheptyl, 3-isopropyl-2-methylhexyl, 3,3-diethylhexyl, 3,4-diethylhexyl, 3-ethyl-2,2-dimethylhexyl, 3-ethyl-2,3-dimethylhexyl, 3-ethyl-2,4-dimethylhexyl, 3-ethyl-2,5-dimethylhexyl, 3-ethyl-3,4-dimethylhexyl, 4-ethyl-2,2-dimethylhexyl, 4-ethyl-2,3-dimethylhexyl, 4-ethyl-2,4-dimethylhexyl, 4-ethyl-3,3-dimethylhexyl, 2,2,3,3-tetramethylhexyl, 2,2,3,4-tetramethylhexyl, 2,2,3,5-tetramethylhexyl, 2,2,4,4-tetramethylhexyl, 2,2,4,5-tetramethylhexyl, 2,2,5,5-tetramethylhexyl, 2,3,3,4-tetramethylhexyl, 2,3,3,5-tetramethylhexyl, 2,3,4,4-tetramethylhexyl, 2,3,4,5-tetramethylhexyl, 3,3,4,4-tetramethylhexyl, n-undecyl, 2-methyldecyl, 3-methyldecyl, 4-methyldecyl, 5-methyldecyl, 3-ethylnonyl, 4-ethylnonyl, 5-ethylnonyl, 2,2-dimethylnonyl, 2,3-dimethylnonyl, 2,4-dimethylnonyl, 2,5-dimethylnonyl, 2,6-dimethylnonyl, 2,7-dimethylnonyl, 2,8-dimethylnonyl, 3,3-dimethylnonyl, 3,4-dimethylnonyl, 3,5-dimethylnonyl, 3,6-dimethylnonyl, 3,7-dimethylnonyl, 4,4-dimethylnonyl, 4,5-dimethylnonyl, 4,6-dimethylnonyl, 5,5-dimethylnonyl, 4-propyloctyl, 4-isopropyloctyl, 3-ethyl-2-methyloctyl, 3-ethyl-3-methyloctyl, 3-ethyl-4-methyloctyl, 3-ethyl-5-methyloctyl, 3-ethyl-6-methyloctyl, 4-ethyl-2-methyloctyl, 4-ethyl-3-methyloctyl, 4-ethyl-4-methyloctyl, 4-ethyl-5-methyloctyl, 5-ethyl-2-methyloctyl, 5-ethyl-3-methyloctyl, 6-ethyl-2-methyloctyl, 2,2,3-trimethyloctyl, 2,2,4-trimethyloctyl, 2,2,5-trimethyloctyl, 2,2,6-trimethyloctyl, 2,2,7-trimethyloctyl, 2,3,3-trimethyloctyl, 2,3,4-trimethyloctyl, 2,3,5-trimethyloctyl, 2,3,6-trimethyloctyl, 2,3,7-trimethyloctyl, 2,4,4-trimethyloctyl, 2,4,5-trimethyloctyl, 2,4,6-trimethyloctyl, 2,4,7-trimethyloctyl, 2,5,5-trimethyloctyl, 2,5,6-trimethyloctyl, 2,6,6-trimethyloctyl, 3,3,4-trimethyloctyl, 3,3,5-trimethyloctyl, 3,3,6-trimethyloctyl, 3,4,4-trimethyloctyl, 3,4,5-trimethyloctyl, 3,4,6-trimethyloctyl, 3,5,5-trimethyloctyl, 4,4,5-trimethyloctyl, 3,3-diethylheptyl, 3,4-diethylheptyl, 3,5-diethylheptyl, 4,4-diethylheptyle, n-dodecyl, 2-methylundecyl, 3-methylundecyl, 4-methylundecyl, 5-methylundecyl, 6-methylundecyl, 2,2-dimethylundecyl, 2,3-dimethylundecyl, 2,4-dimethylundecyl, 2,5-dimethylundecyl, 2,6-dimethylundecyl, 2,7-dimethylundecyl, 2,8-dimethylundecyl, 2,9-dimethylundecyl, 3,3-dimethylundecyl, 3,4-dimethylundecyl, 3,5-dimethylundecyl, 3,6-dimethylundecyl, 3,7-dimethylundecyl, 3,8-dimethylundecyl, 4,4-dimethylundecyl, 4,5-dimethylundecyl, 4,6-dimethylundecyl, 4,7-dimethylundecyl, 5,5-dimethylundecyl, 5,6-dimethylundecyl, 3-ethyldecyl, 4-ethyldecyl, 5-ethyldecyl, 2,2,3-trimethylnonyl, 2,2,4-trimethylnonyl, 2,2,5-trimethylnonyl, 2,2,6-trimethylnonyl, 2,2,7-trimethylnonyl, 2,2,8-trimethylnonyl, 2,3,3-trimethylnonyl, 2,3,4-trimethylnonyl, 2,3,5-trimethylnonyl, 2,3,6-trimethylnonyl, 2,3,7-trimethylnonyl, 2,3,8-trimethylnonyl, 2,4,4-trimethylnonyl, 2,4,5-trimethylnonyl, 2,4,6-trimethylnonyl, 2,4,7-trimethylnonyl, 2,4,8-trimethylnonyl, 2,5,5-trimethylnonyl, 2,5,6-trimethylnonyl, 2,5,7-trimethylnonyl, 2,5,8-trimethylnonyl, 2,6,6-trimethylnonyl, 2,6,7-trimethylnonyl, 2,7,7-trimethylnonyl, 3,3,4-trimethylnonyl, 3,3,5-trimethylnonyl, 3,3,6-trimethylnonyl, 3,3,7-trimethylnonyl, 3,4,4-trimethylnonyl, 3,4,5-trimethylnonyl, 3,4,6-trimethylnonyl, 3,4,7-trimethylnonyl, 3,5,5-trimethylnonyl, 3,5,6-trimethylnonyl, 3,5,7-trimethylnonyl, 3,6,6-trimethylnonyl, 4,4,5-trimethylnonyl, 4,4,6-trimethylnonyl, 4,5,5-trimethylnonyl, 4,5,6-trimethylnonyl.

The term “C₆₋₁₀ aryl”, as used herein, refers to stable mono- or bicyclic ring system having 6-10 ring atoms, of which all the ring atoms are carbon, and which may be substituted or unsubstituted. Aryl includes, for example, phenyl, naphtyl, tolyl, xylyl. The term “unsaturated fatty amine having 12 to 20 carbon atoms and 1 to 3 unsaturated double bonds” as used herein is a derivative of ammonium in which one or two of the hydrogen have been substituted by a long hydrocarbon chain containing 12 to 20 carbon atoms and 1 to 3 carbon-carbon double bonds.

The “unsaturated fatty amine having 12 to 20 carbon atoms and 1 to 3 unsaturated double bonds” may be selected from a group consisting of palmioleyamine, oleylamine, linoleylamine and linolenylamine. In an embodiment, the unsaturated fatty amine is oleylamine (OAm).

OAm can function both as a solvent for the reaction mixture and as a coordinating solvent to stabilize the surface of the particles. It can also coordinate with metal ions, change the form of metal precursors and affect the formation kinetics of nanocrystals during the synthesis.

The term “unsaturated fatty alkene having 12 to 30 carbon atoms and 1 to 6 unsaturated double bonds” is a straight-or branched-chain hydrocarbon having 12 to 30 carbon atoms and 1 to 6 carbon-carbon double bonds. This term includes the structural isomers of the hydrocarbon with 1 to 6 carbon-carbon double bonds.

The “alkene having 12 to 30 carbon atoms and 1 to 6 unsaturated double bonds”, may be selected from a group consisting of 1-octadecene and 1-eicosene, and squalene. In an embodiment, the alkene is 1-octadecene.

The term “saturated fatty alkane having 12 to 30 carbon atoms” is a straight-or branched-chain hydrocarbon having 12 to 30 carbon atoms.

The “saturated fatty alkane having 12 to 30 carbon atoms”, may be selected from a group consisting of octadecane and squalane.

The term “saturated fatty amine having 12 to 20 carbon atoms” as used herein is a derivative of ammonium in which one or two of the hydrogen have been substituted by a long hydrocarbon chain containing 12 to 20 carbon atoms is a straight-or branched-chain hydrocarbon having 12 to 20 carbon atoms.

The “saturated fatty amine having 12 to 20 carbon atoms”, may be selected from a group consisting dodecylamine, tetradecylamine, hexadecylamine, and octadecylamine.

The coordinating agent is a compound that can form stable complexes with metals by coordinating with them through multiple sites. The coordinating agent may be selected in a group consisting of tri-n-octylphosphine (TOP), tri-n-butylphosphine (TBP), tri-n-octylphosphine oxide (TOPO), dodecylphosphonic acid (DDPA), tetradecylphosphonic acid (TDPA), hexadecylphosphonic acid (HDPA), and octadecylphosphonic acid (ODPA).

The molar ratio InX: Sb(NR₁R₂)₃ in step (1) is between 3:1 to 6:1.

The molar ratio InX: coordinating agent in step (2) is between 1:1 to 1:3.

In step (1) b), the mixture is heated to a temperature of less than 100 °C. The mixture in step (1)b) is heated for 30 minutes to 3 hours, under stirring.

According to an embodiment, the mixture in step (1)b) is heated to a temperature of 25 to 100 °C. The mixture in step (1)b) is heated for 30 minutes to 3 hours,

In step (2)a), the temperature at which the solvent or solvent mixture is heated depends on the solvent or solvent mixture (i.e., it should be lower or equal to the boiling point of the latter).

In a preferred embodiment, X is Br or I.

In an embodiment, in step (2)a) the solvent or the solvent mixture as defined above, is first degassed at a temperature of 100 to 130 °C and a vacuum of 10⁻¹ to 10⁻² mbar, for 30 minutes to 2 hours, and then heated to a temperature of 150 to 400 °C.

In an embodiment, the solution obtained in (1) and a coordinating agent in step (2)b) are introduced in the solvent at a temperature 150 to 400 °C, and the resulting mixture is maintained at a temperature of 150 to 400 °C, for 1 minute to 5 hours.

The method of the invention provides a population of InSb quantum dots or nanocrystals having a narrow size distribution with around 10% of standard deviation. The shape of the absorption peak of the InSb quantum dots synthesized by the method of the invention can be modelled with Gaussian function and the position of the maximum can be tuned throughout the wavelength range of the NIR and SWIR regions of the spectrum from 750 to 1900 nm.

The 1^{st} excitonic absorption peaks of the InSb QDs synthesized by the method of the invention exhibit line widths down to around 200 meV (FWHM).

The InSb QDs synthesized using the method of the invention also exhibit a photoluminescence (PL) signal whose intensity can be increased by appropriate surface treatment, using methods known in the state of the art, e.g., overcoating with one or several shell(s) of other semiconductors.

Another object of the present invention is the use of a method according to the invention for manufacturing infrared biological imaging devices, NIR photodetectors, telecommunications (1.4 μm) detectors, solar cells, infrared light-emitting diodes (LEDs), ultrafast field-effect transistors, or thermoelectric devices.

A further object of the invention is a method for manufacturing infrared biological imaging devices, NIR/SWIR photodetectors, telecommunications (1.4 μm) detectors/detectors compatible with the wavelengths used in fiber optics (1.3 and 1.55 μm), solar cells, infrared light-emitting diodes (LEDs), ultrafast field-effect transistors, or thermoelectric devices comprising at least the steps of
a) synthesizing colloidal InSb quantum dots (InSb QDs) according to the method of the invention;
b) surface engineering of InSb QDs;
c) fabrication of InSb QDs thin films; and
d) integration of the QD thin film in the (opto-)electronic device.

The order of steps b), c) and d) will depend on the application. The skilled person is able to adapt the order of steps b), c) and d) depending on the application. A few examples are given below, which are in no way meant to limit the scope of the present invention.

Surface engineering for replacing the initial surface ligands of insulating character with other molecules or ions to enhance the electronic transport in QD solids can be carried out either in the solution phase (before thin film deposition) or in the solid state (on the thin film). Furthermore, the InSb QD thin film will be deposited generally on a dedicated substrate for the given application, e.g., a transparent conducting oxide, such as indium-doped or fluorine-doped tin oxide (ITO, FTO), silicon, graphene. This substrate may contain, depending on the requirements of the targeted application, one or several layers of charge transport/extraction materials (e.g., ZnO, SnO₂, TiO₂ for electrons, NiOₓ, MoOₓ, PEDOT:PSS for holes). Depending on the desired device architecture, the InSb QD film may be coated by one or several charge transport/passivation layer(s) and eventually metal electrodes (e.g., Au, Ag) will be deposited as the top contact of the device. In another configuration, the stack may be reversed, starting with an opaque electrode (e.g., metal or doped silicon) and terminating with a transparent electrode (e.g., ITO, silver nanowires) permitting light transmission.

The surface engineering of the InSb QDs may comprise the growth of one or more inorganic shells, applying for example InAs, InP, ZnSe, ZnS, in a successive manner, or other types of appropriate shell materials for passivating surface trap states and enhancing the luminescence properties. Overcoating with inorganic shell(s) also generally significantly improves the (photo)stability of the QDs and their resistance against chemical degradation. The obtained core/shell QDs can be used, for example, as NIR/SWIR imaging agents in biological detection or as NIR/SWIR emitters based on either photoluminescence or electroluminescence. In the former case, the QDs can be integrated in appropriate matrix materials (e.g., polysiloxanes, polystyrenes), and convert high energy photons into NIR/SWIR photons (down-conversion). In the latter case (electroluminescence), the QDs are embedded in a photodiode structure as mentioned above, comprising electron-and hole-injection layers and a transparent electrode.

The invention will be further illustrated by the following figures and examples.

### EXAMPLES

Below are the details of the synthesis method for InSb nanocrystals or QDs, using In(I)Cl , In(I)Br, or In(I)I in combination with Sb(NMe₂)₃ as the precursors.

### (1) Chemicals

Indium chloride (InCl, 99.995%) and indium bromide (InBr, 99.999%) were purchased from Alfa-aesar. Indium iodide (InI, 99.999%), tris(dimethylamido)antimony (Sb(NMe₂)₃, 99.99%), 1-octadecene (ODE, 90%), and oleylamine (OAm, ≥98%) were purchased from Aldrich. Trioctylphosphine (TOP, 97%) was purchased from Strem. All chemicals were used as received without further purification.

### (2) Synthesis of InSb QDs Using In(I)Cl or In(I)Br and Sb(NMe₂)₃ as Precursors

First, 0.17 mmol of Sb(NMe₂)₃ was dispersed in 0.4 mL of degassed OAm at 50 °C in a glove box. The Sb(NMe₂)₃ was added to 1.0 mmol of In(I)Cl in 1.6 mL of degassed OAm solution to prepare the InSb precursor solution, which was stirred for 1 h at 50 °C in a glove box. In a three-necked round-bottom flask (hereafter rbf), 4 mL of ODE was degassed for 1 h at 120 °C, then heated to 230 °C under Ar atmosphere. After that, 0.3 mL of TOP and the InSb precursor solution were injected into the ODE solvent at 230 °C and the reaction mixture was kept at this temperature and stirred for 3-90 mins.

### (3) Synthesis of InSb QDs Using In(I)I and Sb(NMe₂)₃ as Precursors

The same method as in (2) is applied, but using 0.5 mmol of In(I)I.

### EXAMPLE 1—METHOD OF SYNTHESIS OF COLLOIDAL InSb QUANTUM DOTS (InSb QDs) ACCORDING TO THE INVENTION

### 1.1. Using In(I)Br or In(I)I as the Main Precursor with Sb(NMe₂)₃

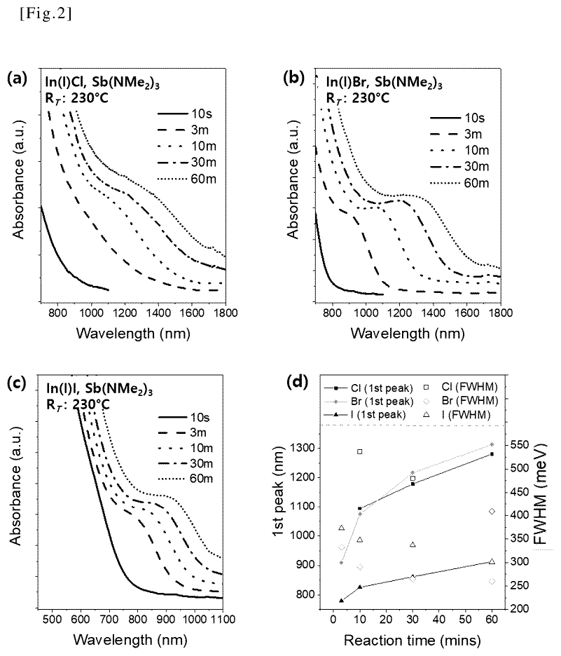

When In(I)Cl was used as precursor with Sb(NMe₂)₃, the 1^{st} excitonic absorption peaks of the InSb QDs could be tuned from 1100 to 1300 nm in 10 to 60 mins at 230 °C (FIG. 2a). However, these syntheses resulted in very broad absorption peaks. Therefore, here the inventors explored for the first time the use of In(I)Br or In(I)I in combination with the aminostibine precursor Sb(NMe₂)₃.

InSb QDs from In(I)Br resulted in QDs with a 1^{st} excitonic absorption peak tunable from 910 to 1310 nm depending on the reaction time (3 to 60 mins) at 230 °C (FIG. 2b). The inventors fitted the 1^{st} excitonic absorption peaks using Gaussian functions to analyze the position of the peak maximum and the line width (full width at half maximum, FWHM).

The use of In(I)Br resulted in the narrowest FWHM showing 260 me V as the minimum value (FIG. 2d, hollow diamonds).

InSb QDs obtained from In(I)I resulted in 1^{st} excitonic absorption peak positions ranging from 780 to 910 nm for reaction times of 3 to 60 min at 230 °C (FIG. 2c). The In(I)I precursor resulted in shorter 1^{st} excitonic absorption wavelengths and thus smaller InSb QD sizes compared to In(I)Br or In(I)Cl. Halide types of In(I)Cl, In(I)Br, and In(I)Cl precursors affect the precursor reactivity. Using In(I)Br or In(I)I precursors in this syntheses method is one of the keys to form high quality of InSb QDs and to achieve a narrow 1^{st} excitonic absorption peak without any additional size-selective purification step.

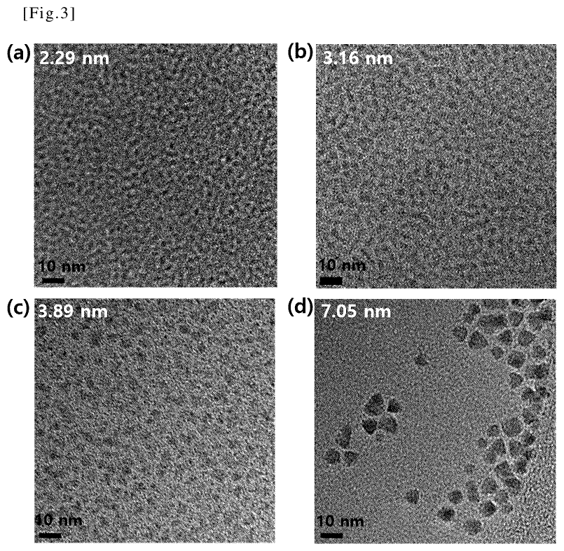

Transmission electronic microscopy (TEM) analysis performed with the TECNAI F20 model operated at 200 kV shows that the size of the InSb QDs synthesized with In(I)Br or In(I)I can be tuned from around 2 to 7 nm (FIGS. 3a, 3b, 3c, 3d).

### 1.2. Synthesis of InSb QDs with Premixing Step of In and Sb Precursors Before Heating (According to the Invention)

Synthesis of InSb QDs with Premixing of In(I)Br and Sb(NMe₂)₃

First, 0.17 mmol of Sb(NMe₂)₃ was dispersed in 0.4 mL of degassed OAm at 50 °C in a glove box.

Premixing step: The Sb(NMe₂)₃ was added to 1.0 mmol of In(I)Br in 1.6 mL of degassed OAm solution to make InSb precursor solution. The stirring of InSb precursor solution was done for 1 h at 50 °C in a glove box.

In a three-necked rbf, 4 mL of OAm was degassed for 1 h at 120 °C, then heated to 230 °C under Ar atmosphere. After that, 0.3 mL of TOP and 2 mL of InSb precursor solution were injected to the OAm solvent at 230 °C and it was stirred for 10 min.

### 1.3. Synthesis of InSb QDs Without Premixing Step of In and Sb Precursors Before Heating (not According to the Invention)

Synthesis of InSb QDs Without Premixing of In(I)Br and Sb(NMe₂)₃

First, 0.17 mmol of Sb(NMe₂)₃ was dispersed in 0.4 mL of degassed OAm at 50 °C in a glove box. In a three-necked rbf, 1.0 mmol of In(I)Br, 0.3 mL of TOP, 5.6 mL of degassed OAm was heated to 230 °C under Ar atmosphere. After that, 0.4 mL of Sb(NMe₂)₃—OAm solution were injected to the rbf containing In(I)Br and it was stirred for 10 min.

### 1.4. Observations

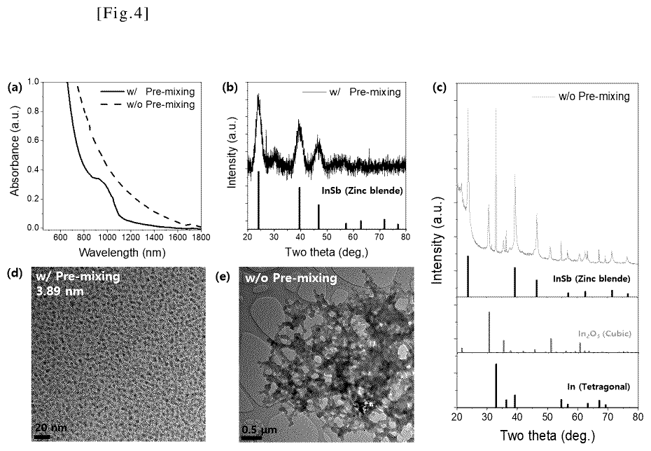

To get pure InSb QDs without any byproducts like In(0), Sb(0) metal, premixing of In(I)X (X=Cl, Br, or I) and Sb(NMe₂)₃ before heating to high temperature is showed to be a critical step in the method according to the invention. Without premixing the precursors, they tend to be reduced resulting in In(0) and Sb(0) metallic products. The synthesis of InSb QDs with and without the premixing step using In(I)Br and Sb(NMe₂)₃ were carried out as described above (FIG. 4).

If premixing step is performed before heating to 230 °C, the products synthesized have a distinct excitonic absorption peak at 940 nm (FIG. 4a) and phase-pure InSb QDs is obtained (FIG. 4b). However, if the Sb(NMe₂)₃-OAm precursor solution is injected into the In(I)Br precursor solution at 230 °C (without the premixing step), most of the product precipitates and the fractions which can be dispersed in organic solvents (e.g. toluene) do not exhibit any excitonic absorption feature (FIG. 4a). Powder X-ray diffraction using a Bruker D8 powder diffractometer, reveals that the products formed without premixing are In(0) metal, and its oxidation product In₂O₃ as well as very large-sized InSb nanoparticles (FIG. 4c). Likewise TEM images performed on a TECNAI F20 electron microscope operated at 200 kV show homogeneous InSb QDs in the case of premixing (FIG. 4d) while for the sample without premixing, inhomogeneous big aggregates are formed (FIG. 4e).

Premixing of the In and Sb precursors is thus a very important step to get high-quality InSb QDs characterizing the present synthesis method.

### EXAMPLE 2: INFLUENCE OF THE SOLVENT ON THE PROPERTIES OF THE InSb QDs

1-Octadecene (ODE) or oleylamine (OAm) is used as the reaction solvent in the examples of the method of the invention. (Note that in both cases, 1.6 mL of OAm are used for the preparation of the In—Sb premixed precursor, as described above). ODE is a non-coordinating solvent for metal ions while OAm can coordinate metal ions and the QD surface with its amine functional group.

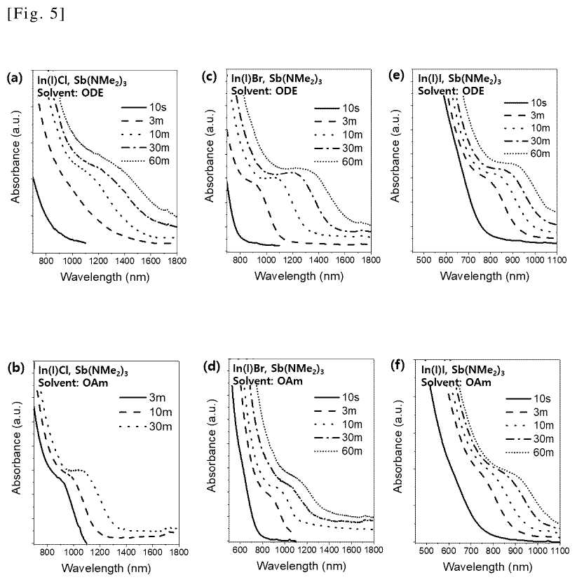

For the In(I)Cl precursors, both solvents resulted in an uncontrolled growth of the InSb QDs showing broad absorption peaks for the ODE case and the limited tunability of the 1^{st} excitonic absorption wavelength for the OAm case (FIGS. 5a, 5b).

ODE is the better choice for In(I)Br or In(I)I precursors compared to OAm (FIGS. 5c, 5d, 5e, 5f) as can be judged from the line widths of the 1^{st} excitonic absorption peaks of InSb QDs. When InSb QDs are prepared with In(I)Br or In(I)I precursors in ODE, narrower line widths are achieved than in the case of OAm (FIG. 5g). For this reason, in the present synthesis method ODE is the preferred solvent for the synthesis of high-quality InSb QDs.

### EXAMPLE 3: INFLUENCE OF THE REACTION TEMPERATURE ON THE PROPERTIES OF THE InSb QDs

The reaction temperature is another highly important parameter for tuning the size and hence the 1^{st} excitonic absorption wavelength of InSb QDs. Higher temperatures lead to faster growth of the InSb QDs shifting their absorption onset to longer wavelength. The reaction temperatures were varied in a range of 230 to 280 °C for In(I)Br and In(I)I precursors in ODE. For lower temperatures a sluggish growth was observed. For higher temperatures a broadening of the spectral features due to ripening and no further growth were observed.

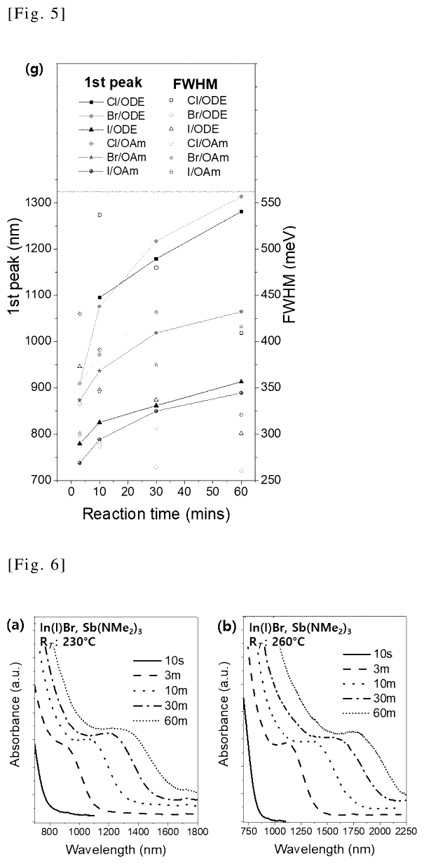

For the In(I)Br precursors, the 1^{st} excitonic peak could be tuned from 910 to 1300 nm at 230 °C (FIG. 6a), from 1140 to 1760 nm at 260 °C (FIG. 6b), and 1320 to 1730 nm 280 °C (FIG. 6c) with narrow FWHM (FIG. 6d).

In the case of In(I)I precursors, the 1^{st} excitonic peak could be tuned from 780 to 910 nm at 230 °C (FIG. 6e), from 860 to 1160 nm at 260 °C (FIG. 6f), and 890 to 1250 nm 280 °C (FIG. 6g) with narrow FWHM (FIG. 6h).

From these results, the best conditions for synthesizing small QDs in the range of 2-4 nm are the use of In(I)I at 230 °C, for growing larger ones (4-7 nm), In(I)Br and 260 °C should be used.

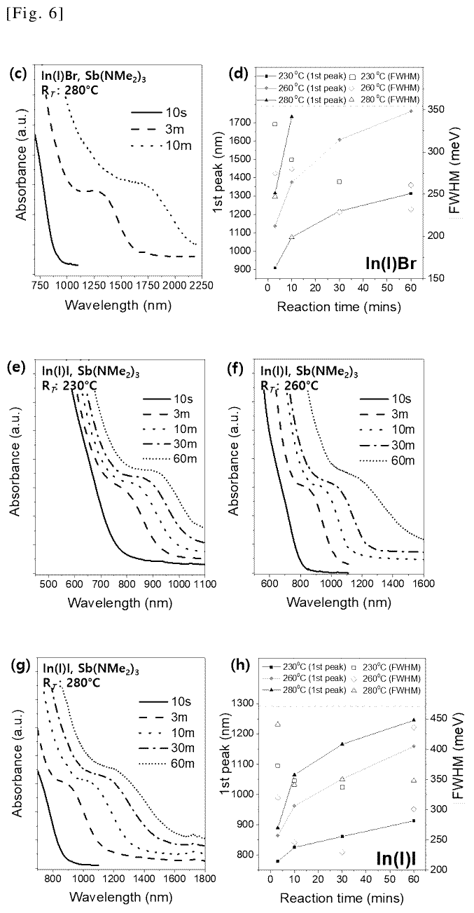

Similar reactions were conducted in OAm as the reaction solvent (cf. previous paragraph) using temperatures in a range of 210-320 °C and In(I)I as the In precursor (FIG. 7). At 210 °C, no well-defined excitonic peak is obtained (FIG. 7a). From 230 to 280 °C, the 1^{st} excitonic peak could be tuned from 740 to 890 nm, at 230 °C (FIG. 7 b), from 940 to 1120 nm, at 250 °C (FIG. 7c), and from 1000 to 1060 nm, at 280 °C (FIG. 7d). At 320 °C, the InSb QDs started to aggregate and precipitate (FIG. 7e).

Once again, the suitable reaction temperatures range from 230 to 280°C with the 1^{st} excitonic absorption wavelength ranging from 740 to 1120 nm (FIG. 7f).

At lower temperature (230 °C), the shape of the InSb QDs is spherical (FIG. 7g), while at higher temperature (280 °C), branched InSb structures form (FIG. 7h).

### EXAMPLE 4: EFFECTS of the In:Sb PRECURSORS MOLAR RATIO

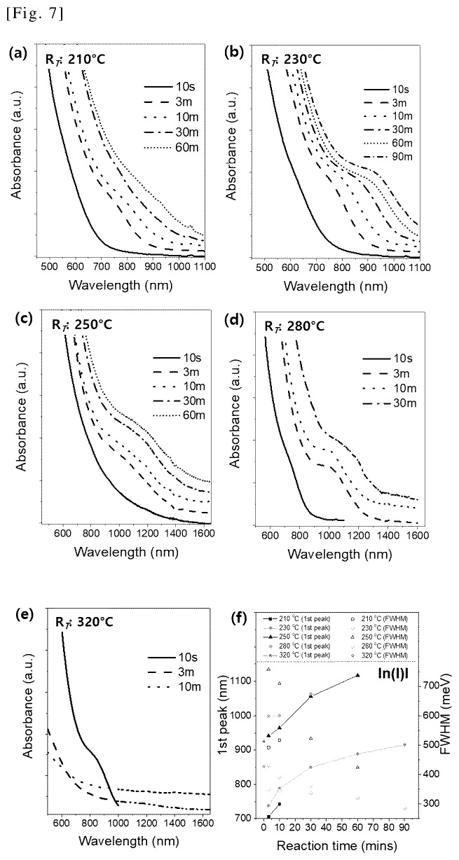

In the method of the invention, 6 equivalents of In(I)Cl or In(I)Br compared to Sb(NMe₂)₃ are used to synthesize high-quality InSb QDs and 3 equivalents of In(I)I compared to Sb(NMe₂)₃. Theoretically, 3 equivalents of In(I)X (X=Cl, Br, or I) are required to reduce Sb in one Sb(NMe₂)₃ molecule to the required—3 oxidation state. However, in the case of In(I)Cl and In(I)Br precursors, In(0) metal formation is competing with the In—Sb complex formation during the premixing phase of the In and Sb precursors. As a result, when only 3 equivalents of In(I)Cl are used compared to Sb(NMe₂)₃, QDs with featureless absorption spectra were obtained with low chemical yield (FIG. 8a). To the contrary, the use of 6 equivalents of In(I)Cl afforded InSb QDs with clearly visible and size-tunable excitonic peak (FIGS. 8b, 8c). The In(I)Br precursor showed a similar behavior: 6 equivalents of In(I)Br resulted in a narrower line width of the 1^{st} excitonic absorption peaks compared to 3 equivalents (FIGS. 8d, 8e, 8f).

### EXAMPLE 5: EFFECT OF THE LIGANDS ON THE PROPERTIES OF THE InSb QDs

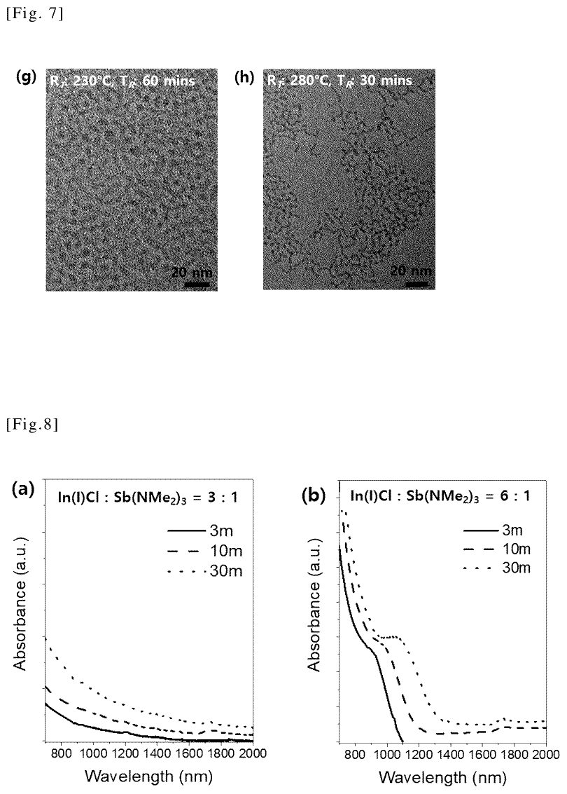

In the method of the invention, trioctylphosphine (TOP) is additionally used in the reaction solution with a 3:1:4 molar ratio of In(I)I: Sb(NMe₂)₃: TOP to obtain narrow 1^{st} excitonic absorption peaks (FIG. 9 a). Using twice the amount of TOP resulted in similar absorption features (FIG. 9b). However, without TOP, the absorption peaks are broader (FIG. 9c). Also, TOP is working better than tributylphopshine (TBP) (FIG. 9d). Dodecylphosphonic acid (DDPA), added as a second ligand, strongly affects the growth kinetics of the InSb QDs leading to broad spectral features (FIG. 9e).

### EXAMPLE 6: INFLUENCE OF THE PRECURSOR CONCENTRATION

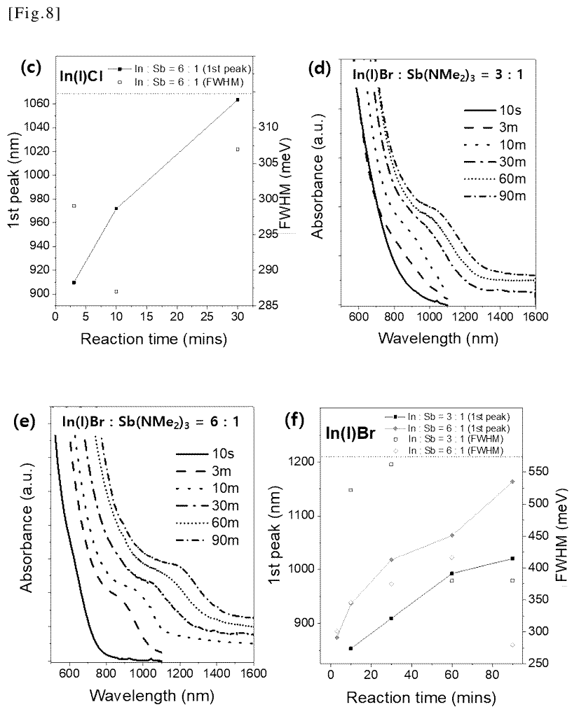

Changing the total precursor concentration does not make a big difference but in the diluted condition with 40 mM of In(I)I and 13 mM of Sb(NMe₂)₃ compared to the standard condition with 80 mM of In(I)I and 26 mM of Sb(NMe₂)₃, Ostwald ripening occurred leading to the broadening of the absorption peaks at the end of the growth stage (FIGS. 10a, 10b, 10c).

### EXAMPLE 7: PL PROPERTIES of InSb QDs

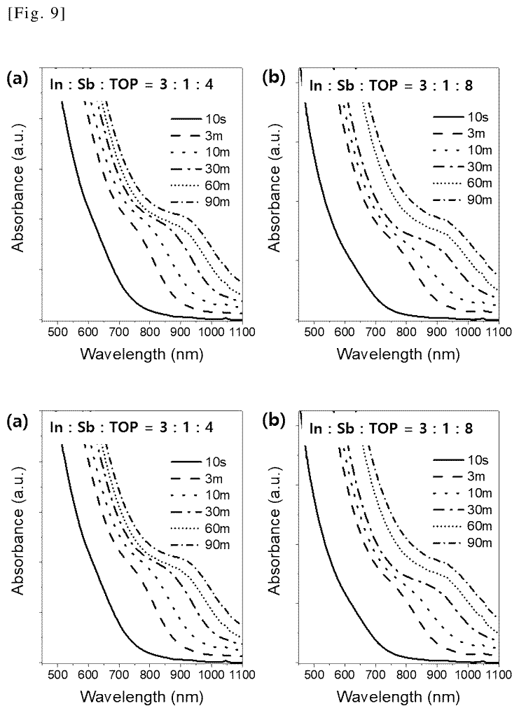

The synthesized InSb QDs exhibit a photoluminescence (PL) signal detectable with a Horiba Fluorolog 3 spectrophotometer equipped with a Hamamatsu R5509 NIR photomultiplier tube. For a representative InSb QD sample, the PL peak at 1314 nm exhibits a line width of 150 me V and a Stokes shift of 171 meV (FIG. 11).

### EXAMPLE 8:¹H-NMR ANALYSES FOR THE PREMIXED InSb PRECURSORS SOLUTION

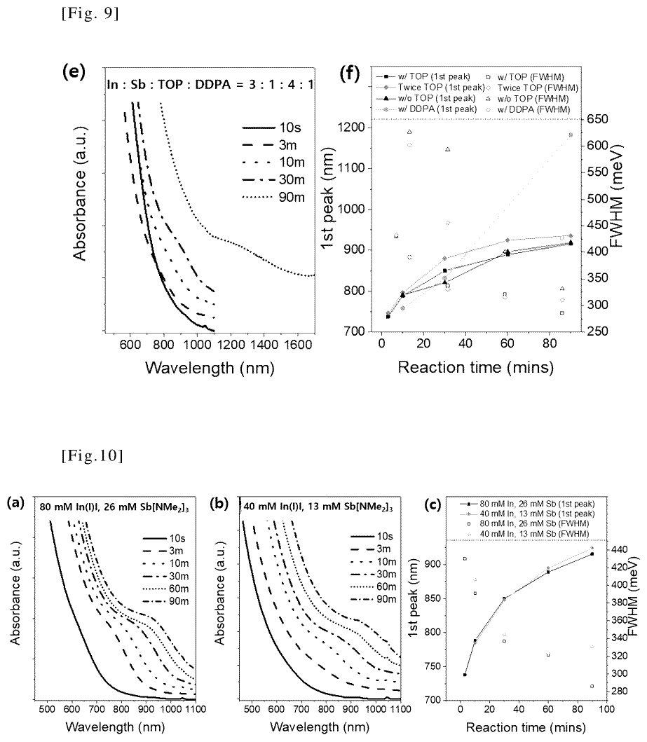

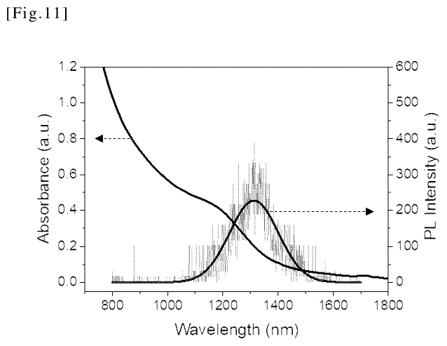

¹H-NMR experiments were performed to investigate the reaction product of the premixing stage of In(I)I and Sb(NMe₂)₃ with amine ligands (FIG. 12). For the amine ligands, we used dodecylamine (DDA) instead of OAm because DDA has a higher purity than OAm. First, we confirmed DDA did not affect the synthesis results significantly compared to OAm (FIG. 13). Deuterated toluene is used as the solvent. Sb(NMe₂)₃ has only one singlet peak at 2.78 ppm of chemical shift which originated from methyl protons of −N(CH₃)₂ (FIG. 12a). DDA, CH₃(CH₂)₁₁NH₂, has four distinct ¹H-NMR peaks at 0.68, 0.97, 1.34, and 2.57 ppm corresponding to the protons are from —NH, —CH₃,—CH₂—, and —N(CH₂)—, respectively (FIG. 12b). Once Sb(NMe₂)₃ is mixed with 3 equiv. of DDA, two new peaks appeared, a singlet at 2.26 ppm and a triplet at 3.73 ppm (FIG. 12c). The singlet at 2.26 ppm is corresponding to methyl protons of dimethylamine (DMA), (CH₃)₂NH, which is one of the side-products from the transamination reaction between Sb(NMe₂)₃ and DDA producing Sbₓ[(CH₃)₂N]_{3-y}[CH₃(CH₂)₁₁NH]_{y}. The triplet at 3.75 ppm is attributed to —N(CH₂)— from DDA bound to Sb. The peak area ratio of those peaks is 3 to 1 as expected for the transamination reaction. The peak at 3.75 ppm of —N(CH₂)— in DDA bound to Sb is shifted from 2.57 ppm of —N(CH₂)— in DDA due to the deshielding effect of Sb. Meanwhile, the other peaks from free DDA remained at the same chemical shift when 3 equiv. of DDA were mixed with Sb(NMe₂)₃. There is residual broad peak at 2.57 ppm, indicating that not all 3 equiv. of DDA reacted with 1 equiv. of Sb(NMe₂)₃ (FIG. 12c).

The inventors also analyzed the ¹H-NMR spectra for the reaction of In(I)I with DDA. When In(I)I is mixed with 3 equiv. of DDA, two —N(CH₂)— peaks are observed, a broad signal at 2.54 ppm and a triplet at 2.64 ppm (FIG. 12d). Because of the disproportionation equilibrium of In(I)I, three types of indium, In(I)I, In(III)I₃, and In(0), are present in the In(I)I-DDA solution and the In(0) exists in a particle form. Therefore, three types of In-DDA can be formed such as In(I)I(DDA)ₓ, In(III)I₃(DDA)_{y}, and DDA bound In(0) particle surfaces. The broadened peak at 2.54 ppm corresponds to —N(CH₂)— of the DDA bound In(0) particle surfaces and the triplet peak at 2.64 ppm corresponds to —N(CH₂)— of In(I)I(DDA)_{y} and In(III)I₃(DDA)ₓ (FIG. 12c). After all, the inventors mixed 3 equiv. of In(I)I and 3 equiv. of DDA with 1 equiv. of Sb(NMe₂)₃, which resulted in a yellow/brownish solution. A singlet from DMA appeared at 2.18 ppm with a slightly shifted value showing that the transamination between Sb(NMe₂)₃ and DDA occurred (FIG. 12d). Meanwhile, the triplet of —N(CH₂)— from DDA bound to Sb, which is positioned at 3.75 ppm, completely disappeared suggesting that Sb(III) coordinates to In(I) (FIG. 12e). Thus, the missing peak of 3.75 ppm from —N(CH₂)— of DDA bound to Sb suggests that the In(I)I and Sb(NMe₂)₃ form intermediate complexes or clusters containing preformed In—Sb bonds.

### EXAMPLE 9: GROWTH OF InSb QDs BY ADDING A SECOND PRECURSOR SOLUTION

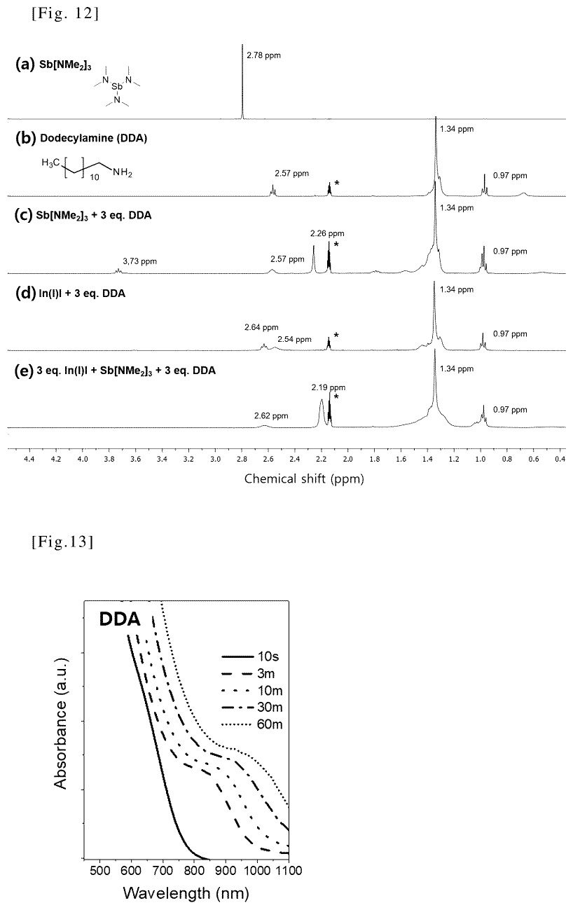

The excitonic absorption peaks of InSb QDs could be tuned from 750 to 1800 nm by varying the halide precursor types, reaction temperature, and times, especially for In(I)Br or In(I)I precursors. The excitonic absorption peaks can be further extended from 1800 to 1900 nm by adding a second precursor solution containing In(I)Br and Sb(NMe₂)₃ using a syringe pump (FIG. 14). For the second precursor addition, the InSb precursor solution is made again using 0.25 mmol of In(I)Br, and 0.04 mmol of Sb(NMe₂)₃ in 0.75 mL of OAm for 1 hr at 50 °C. The second precursor solution is injected by a syringe pump with 3 mL/hr of the pumping rate into the InSb QDs solution at 260 °C for 15 mins.

### EXAMPLE 10: SYNTHESIS InSb QDs USING THE SO-CALLED “HEAT-UP” METHOD

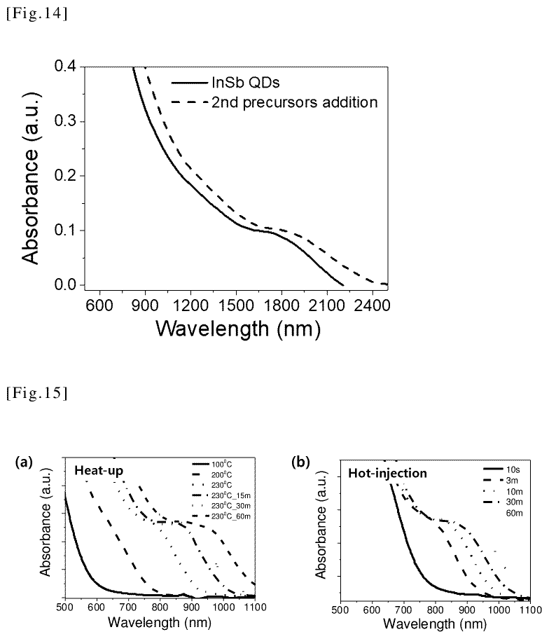

The InSb QDs can be synthesized using the heat-up method as well as via hot-injection. In one example of the heat-up synthesis, the InSb precursor solution was prepared using 0.5 mmol of In(I)I and 0.17 mmol of Sb(NMe₂)₃ in OAm, and the resulting InSb precursor solution was injected into the ODE solvent at room temperature (25 °C). The reaction solution was heated to 230 °C with 20 °C/mins of the heating rate. When the reaction temperature rose to 200 °C, the excitonic absorption peaks of InSb QDs appeared around 650 nm with broad features (FIG. 15a). The excitonic absorption peaks shifted to 780 nm at 230 °C and then to 940 nm over time. Compared to the hot-injection synthesis using otherwise identical reaction conditions (FIG. 15b), the heat-up method resulted in this example in a slightly narrower line width of the excitonic absorption peaks. For example, the line widths (FWHM) are 284 me V for the heat-up sample and 337 meV for the hot-injection sample which were obtained after keeping the temperature at 230 °C for 30 min.

1. A method of synthesis of colloidal InSb quantum dots (InSb QDs) comprising the following steps:
(1) obtaining a solution by premixing In and Sb precursors, wherein:
(a) the Sb precursor comprises a solution containing of Sb(NR₁R₂)₃ with R₁ and R₂, independently, being a C₁-C₈ alkyl and/or C₆-C₁₀ aryl, in a saturated fatty amine having 4 to 20 carbon atoms or an unsaturated fatty amine having 12 to 20 carbon atoms and 1 to 3 unsaturated double bonds; and
(b) the In precursor comprises a solution containing In(I)X with X being Cl, Br or I, in a saturated fatty amine having 12 to 20 carbon atoms or an unsaturated fatty amine having 12 to 20 carbon atoms and 1 to 3 unsaturated double bonds, or a saturated fatty alkane having 12 to 30 carbon atoms, or in an unsaturated fatty alkene having 12 to 30 carbon atoms and 1 to 6 unsaturated double bonds, or in a mixture of several of these compounds;
(2) heating the solution obtained in (1) to a temperature of less than 100 °C, under stirring; and
(3) synthesizing InSb quantum dots (InSb QDs) by
(a) heating a solvent or a solvent mixture to a temperature of 150 to 400 °C, wherein the solvent or the solvent mixture is selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds; and
(b) introducing into the solvent or the solvent mixture of (a) the solution obtained in (2) and a coordinating agent selected in a group consisting of C₄-C₂₅ alkyl phosphines, C₄-C₂₅ alkyl phosphine oxides, C₄-C₂₅ alkyl phosphonic acids, C₄-C₂₅ alkyl phosphinic acids, wherein the solution obtained in (2) and a coordinating agent are introduced at a temperature of:
(i) 150 to 400 °C, and the resulting mixture is maintained at a temperature of 150 to 400 °C, for 1 minute to 5 hours, under stirring; or
(ii) 20 to 30 °C, and the resulting mixture is heated with a temperature rise to 150 to 400 °C, and the resulting mixture is maintained at a temperature of 150 to 400 °C, for 1 minute to 5 hours, under stirring.

2. The method according to claim 1, wherein the unsaturated fatty amine having 12 to 20 carbon atoms and 1 to 3 unsaturated double bonds, is selected from a group consisting of palmitoleylamine, oleylamine, linolylamine, linolenylamine, and petroselinylamine.

3. The method according to claim 1 wherein the unsaturated fatty alkene having a 12 to 20 carbon atoms and 1 to 6 unsaturated double bonds is selected from a group consisting of 1-octadecene, 1-eicosene, and squalene.

4. The method according to claim 1, wherein the saturated fatty alkane having 12 to 30 carbon atoms is selected from a group consisting of octadecane and squalane.

5. The method according to claim 1, wherein the saturated fatty amine having 12 to 20 carbon atoms, is selected from a group consisting of dodecylamine, tetradecylamine, hexadecylamine, and octadecylamine.

6. The method according to claim 1, wherein the coordinating agent is selected from a group consisting of tri-n-octylphosphine (TOP), tri-n-butylphosphine (TBP), tri-n-octylphosphine oxide (TOPO), dodecylphosphonic acid (DDPA), tetradecylphosphonic acid (TDPA), hexadecylphosphonic acid (HDPA), and octadecylphosphonic acid (ODPA).

7. The method according to claim 1, wherein the InX: Sb(NR₁R₂)₃ molar ratio in step (1) is between 3:1 to 6:1.

8. The method according to claim 1, wherein the InX: coordinating agent molar ratio in step (3)(b) is between 1:1 to 1:3.

9. The method according to claim 1, wherein the solution mixture in step (2) is heated to a temperature of 25 to 100 °C.

10. The method according to claim 1, wherein the solution in step (2) is heated for 30 minutes to 3 hours.

11. The method according to claim 1, wherein the solvent in step (3)(a) is first degassed at a temperature of 100 to 130 °C at a vacuum of 10⁻¹ to 10⁻² mbar for 30 minutes to 2 hours, and then heated to 150 to 400 °.

12. The method according to claim 1, wherein the solution obtained in (1) and a coordinating agent in step (3)(b) are introduced in the solvent or solvent mixture at a temperature 150 to 400 °C, and the resulting mixture is maintained at a temperature of 150 to 400 °C, for 1 minute to 5 hours.

13. (canceled)

14. A method for manufacturing an (opto-) electronic device, the method comprising the steps of:
(a) synthesizing colloidal InSb quantum dots (InSb QDs);
(b) surface engineering of InSb QDs;
(c) fabrication of InSb QDs thin films; and
(d) integration of the QD thin film into the (opto-)electronic device,
wherein the colloidal InSb quantum dots (InSb QDs) are synthesized by a method comprising the steps of:
(1) obtaining a solution by premixing In and Sb precursors, wherein:
(a) the Sb precursor comprises a solution containing of Sb(NR₁R₂)₃ with R₁ and R₂, independently, being a C₁-C₈ alkyl and/or C₆-C₁₀ aryl, in a saturated fatty amine having 4 to 20 carbon atoms or an unsaturated fatty amine having 12 to 20 carbon atoms and 1 to 3 unsaturated double bonds; and
(b) the In precursor comprises a solution containing In(I)X with X being Cl, Br or I, in a saturated fatty amine having 12 to 20 carbon atoms or an unsaturated fatty amine having 12 to 20 carbon atoms and 1 to 3 unsaturated double bonds, or a saturated fatty alkane having 12 to 30 carbon atoms, or in an unsaturated fatty alkene having 12 to 30 carbon atoms and 1 to 6 unsaturated double bonds, or in a mixture of several of these compounds:
(2) heating the solution obtained in (1) to a temperature of less than 100 °C, under stirring; and
(3) synthesizing InSb quantum dots (InSb QDs), by:
(a) heating a solvent or a solvent mixture to a temperature of 150 to 400 °C, wherein the solvent or the solvent mixture is selected from a group consisting of saturated fatty amine having 12 to 20 carbon atoms or an unsaturated fatty amine having 12 to 20 carbon atoms and 1 to 3 unsaturated double bonds, an unsaturated fatty alkene having 12 to 30 carbon atoms and 1 to 6 unsaturated double bonds; and
(b) introducing into the solvent or the solvent mixture of (a) the solution obtained in (2) and a coordinating agent selected in a group consisting of C₄-C₂₅ alkyl phosphines, C₄-C₂₅ alkyl phosphine oxides, C₄-C₂₅ alkyl phosphonic acids, C₄-C₂₅ alkyl phosphinic acids, wherein the solution obtained in (2) and a coordinating agent are introduced at a temperature of:
(i) 150 to 400 °C, and the resulting mixture is maintained at a temperature of 150 to 400 °C, for 1 minute to 5 hours, under stirring; or
(ii) 20 to 30 °C, and the resulting mixture is heated with a temperature rise to 150 to 400 °C, and the resulting mixture is maintained at a temperature of 150 to 400 °C, for 1 minute to 5 hours, under stirring.

15. The opto-electronic device of claim 14, wherein the opto-electronic device is selected from an infrared biological imaging device, a NIR/SWIR photodetector, a telecommunications (1.4 pm) detector, a solar cell, an infrared light-emitting diode (LED), a field-effect transistor, or a thermoelectric device.
